(19) United States
(12) Patent Application Publication
(10) Pub. No.: US 2024/0090262 A1
(43) Pub. Date: Mar. 14, 2024

(54) MANUFACTURING METHOD OF DISPLAY AND DISPLAY

(71) Applicants: JSR CORPORATION, Tokyo (JP); Mattrix Technologies, Inc, Gainesville, FL (US)

(72) Inventors: Hiromitsu Katsui, Minato-ku (JP); Bo Liu, Gainesville, FL (US); Maxime Lemaitre, Gainesville, FL (US)

(21) Appl. No.: 18/275,741

(22) PCT Filed: Jan. 31, 2022
(86) PCT No.: PCT/JP2022/003505

§ 371 Date: Aug. 3, 2023

Related U.S. Application Data
(60) Provisional application No. 63/300,540, filed on Jan. 18, 2022.

(30) Foreign Application Priority Data
Feb. 3, 2021 (JP) 2021-015505

(51) Int. Cl. H10K 59/121; H10K 59/12

(52) U.S. Cl. CPC H10K 59/1213; H10K 59/1201

(57) ABSTRACT

Provided is a manufacturing method of a display including a vertical organic light-emitting transistor in which a wider light-emitting area is secured while manufacturing time and manufacturing cost are suppressed. In the manufacturing method of the display including the vertical organic light-emitting transistor, a gate electrode layer of the vertical organic light-emitting transistor and one of current-carrying electrode layers of a thin-film transistor connected to the gate electrode layer of the vertical organic light-emitting transistor are formed integrally in the same layer.

### TECHNICAL FIELD

The present invention relates to a manufacturing method of a display and a display.

### BACKGROUND ART

In recent years, the practical use of a light source element using an organic semiconductor light-emitting element has progressed, and a display using an organic semiconductor light-emitting element as a light source element has become commercially available. In the development of displays that use organic semiconductor light-emitting elements as light source elements, studies on higher brightness, higher definition, lower power consumption, and longer life have still been conducted in order to further improve performance.

Pixels of conventional display using the organic semiconductor light-emitting element as the light-emitting element are constituted of an organic light-emitting diode (also referred to as “OLED”) and a transistor that controls a current flowing through the organic light-emitting diode. The organic light-emitting diode is a device that emits light in response to the current input from a thin-film transistor (also referred to as “TFT”) formed on a substrate to an organic electroluminescent (EL) layer sandwiched between an anode electrode and a cathode electrode.

However, with respect to this configuration, Patent Document 1 below describes a vertical organic light-emitting transistor (also referred to as “VOLET”), as an element configured to reduce the number of control elements and increase the brightness by increasing the light-emitting area, which is configured to adjust the flowing current by controlling the voltage applied to a gate electrode, and meanwhile, emit light according to an amount of current flowing through the transistor itself. Further, Patent Document 2 below describes a display using a vertical organic light-emitting transistor, and the above described elements are expected to significantly increase the brightness of the display.
PTL 1: Patent Document 1: WO 2009/036071 A
PTL 2: Patent Document 2: JP-A-2014-505324

### SUMMARY OF THE INVENTION

A display using organic EL is expected to be applied not only to home televisions and smartphones, but also to advertising displays displayed on pillars installed in such as train stations. Therefore, the organic EL display is required to be provided at a lower cost while improving the performance and quality such as brightness and resolution according to the usage mode.

However, without optimizing the process flow, a display provided with a vertical organic light-emitting transistor has more number of manufacturing processes and a higher manufacturing cost than a display provided with the conventional organic light-emitting diode.

The display provided with the vertical organic light-emitting transistor has an advantage that the number of thin-film transistors can be reduced as compared with the display provided with the conventional organic light-emitting diode. However, because the thin-film transistors are formed at different positions in the same layer at the same time, the influence on the number of manufacturing processes and the manufacturing cost due to the increase in the number of transistors is small.

Further, based on the standard, non-optimized process flow, the display provided with the vertical organic light-emitting transistor requires more manufacturing processes to form an additional gate electrode and a gate insulating film layer than a display provided with a simple organic light-emitting diode. Therefore, in the manufacturing process of the display including the organic light-emitting diode, simply replacing the process of forming the organic light-emitting diode with the process of forming the vertical organic light-emitting transistor increases the time and cost required for manufacturing.

In view of the above problems, it is an object of the present invention to provide a manufacturing method of a display including a vertical organic light-emitting transistor in which a wider light-emitting area is secured while suppressing manufacturing time and manufacturing cost.

A manufacturing method of a display according to the present invention is a manufacturing method of a display including a vertical organic light-emitting transistor, the method including:
forming integrally on a same layer, a gate electrode layer of the vertical organic light-emitting transistor and one of current-carrying electrode layers of a thin-film transistor connected to the gate electrode layer of the vertical organic light-emitting transistor.

In the present specification, the current-carrying electrode layer of the thin-film transistor is used as a general term for a source electrode layer and a drain electrode layer of the thin-film transistor. In many thin-film transistors formed as components of a display, the source electrode layer and the drain electrode layer are formed in the same layer separated by a channel length. The current-carrying electrode layer of the thin-film transistor is classified into the source electrode layer or the drain electrode layer according to wiring and nodes to be connected.

A display in which a pixel is constituted of the organic semiconductor light-emitting element and the thin-film transistor is formed with, on the lower layer side, a thin-film transistor, a gate line for transmitting a signal to the thin-film transistor for each pixel, a current supply line for supplying the current to the organic semiconductor light-emitting element, and others. Then, the organic semiconductor light-emitting element is formed on the upper layer side of the thin-film transistor, the current supply line, and the others. In the following description, for convenience of explanation, the configuration is described assuming that the upper layer side indicates a direction of laminating each layer from the substrate side.

The display using the organic light-emitting diode as the light-emitting element requires at least two thin-film transistors for current control and for supply switching as a configuration for driving and controlling one organic light-emitting diode. On the other hand, the display using the vertical organic light-emitting transistor as the light-emitting element has a configuration of driving and controlling one vertical organic light-emitting transistor, in which only one thin-film transistor whose current-carrying electrode layer (which is assumed to be the drain electrode layer in the following description) is connected to the gate electrode layer of the vertical organic light-emitting transistor.

Further, because the gate electrode layer of the vertical organic light-emitting transistor is a terminal for controlling the electric field between the source electrode layer and the drain electrode layer of the vertical organic light-emitting transistor, the gate electrode will not be connected with low impedance to nodes other than the current-carrying electrode layer of the thin-film transistor. For this reason, even if the gate electrode layer of the vertical organic light-emitting transistor and one of the current-carrying electrode layers of the thin-film transistor connected to the gate electrode layer are formed integrally, a problem of voltage IR drop due to high current separately flowing through a parallel conductive path with other nodes will not occur.

Therefore, by adopting the above manufacturing method, the process of forming the gate electrode layer of the vertical organic light-emitting transistor and the process of forming the current-carrying electrode layer of the thin-film transistor can be performed at the same time. Therefore, the number of processes is reduced as compared with the case of forming the above transistors by separate processes.

Further, because the display manufactured by the above manufacturing method does not require a contact hole between the gate electrode layer of the vertical organic light-emitting transistor and the current-carrying electrode layer of the thin-film transistor, the wider light-emitting area can be secured.

In the manufacturing method, the vertical organic light-emitting transistors may have at least two or more source electrode layers formed integrally on the same layer.

By using the manufacturing method, the source electrode layer and the current supply line of the vertical organic light-emitting transistor provided in each light-emitting area are not necessarily connected to each other by another wiring. That is, the number and area of the current supply lines that supply current to the source electrode layer of each vertical organic light-emitting transistor are reduced.

Conventionally, the current supply lines are formed in a grid pattern over the entire display between the vertical organic light-emitting transistors formed in an array. However, according to the manufacturing method, when a driver that supplies the current for driving the vertical organic light-emitting transistor is connected to at least one vertical organic light-emitting transistor, the current is supplied to the remaining vertical organic light-emitting transistors through the integrally constituted source electrode. That is, the number and area of the current supply lines that supply the current to the source electrode layer are reduced, the area for forming the current supply lines is significantly reduced, and the materials required for forming the current supply lines are significantly reduced.

In the case of forming the current supply line on the gate insulating film of the vertical organic light-emitting transistor and forming the source electrode of the vertical organic light-emitting transistor integrally so as to straddle the plurality of vertical organic light-emitting transistors, because the formation of the contact holes for connection is not required and a complicated pattern does not need to be formed, the manufacturing time and the manufacturing cost do not increase significantly.

Further, because the source electrode layer of the vertical organic light-emitting transistor formed integrally on the same layer has a function of sharing the current flowing through the current supply line, the influence of voltage drop due to parasitic resistance or the like is suppressed. Further, the area created by reducing the current supply line can be used to expand the light-emitting area.

In the manufacturing method, the source electrode layer of the vertical organic light-emitting transistor may be formed after a surface layer serving as a base is formed, by forming a thin film or a percolating network of a conductive material on a main surface of the surface layer.

By using the manufacturing method, for example, the source electrode layer of the vertical organic light-emitting transistor can be formed of conductive material such as carbon material, which is difficult to fix and form the electrode layer by itself. Further, for example, the surface layer can be formed so as to straddle the plurality of vertical organic light-emitting transistors, and the source electrode can be formed so as to straddle a part of the vertical organic light-emitting transistors. By adopting the above configuration, the material cost can be suppressed by forming the source electrode layer with the configuration in consideration of the influence of the wiring impedance of the current supply line.

Here, as the conductive material laminated on the main surface of the surface layer, for example, carbon nanotubes, graphene, graphite, metal nanowires and the like can be adopted.

In the manufacturing method, after the surface layer is formed, a part of the main surface of the surface layer may be formed with a current supply line configured to supply current to the source electrode layer of the vertical organic light-emitting transistor, and
after the current supply line is formed, the source electrode layer of the vertical organic light-emitting transistor may be formed of the conductive material so as to straddle the surface layer and the current supply line.

By the manufacturing method, the current supply line can be formed in an area sandwiched between the vertical organic light-emitting transistors. This eliminates the need to secure an area for forming the current supply line in a layer below the vertical organic light-emitting transistor. This configuration can secure the wider light-emitting area, particularly in the above-described display in which a bottom emission method is adopted.

In the manufacturing method, the gate electrode layer of the vertical organic light-emitting transistor may be formed of a material made of metal oxide that exhibits conductivity and transparency to light.

In addition, the manufacturing method may further include forming a color filter layer that transmits light in a part of a wavelength band of light emitted from the vertical organic light-emitting transistor.

The display according to the present invention includes: a vertical organic light-emitting transistor; and a thin-film transistor in which one of the current-carrying electrode layers is connected to a gate electrode layer of the vertical organic light-emitting transistor, in which the gate electrode layer of the vertical organic light-emitting transistor and the one of the current-carrying electrode layer of the thin-film transistor are formed integrally on a same layer. Typically, both current-carrying electrodes of the thin-film transistor, namely the source electrode and the drain electrode will be formed integrally on the same layer in the same process. Additionally, the source electrode of the thin-film transistor and the data line will be formed integrally on the same layer in the same process. Therefore, the data line, the source electrode and drain electrode of the thin-film transistor, and the gate electrode of the vertical organic light-emitting transistor can all be formed integrally on the same layer in the same process. Higher electrical conductivity is desired for the data line to ensure refresh rate, while high optical transparency is needed for the gate electrode of the vertical organic light-emitting transistor for a bottom emission display method. Good balance between electrical conductivity and optical transparency of the layer is desirable. Alternatively, the gate electrode of the vertical organic light-emitting transistor can be formed as a transparent and conductive component of a multi-layered structure, where in the data line, the source electrode and drain electrode of the thin-film transistor portion of the multi-layered structure in which optical transparency is not required, opaque but highly conductive metal layer component can be incorporated to enhance electrical conductivity.

In the display, the vertical organic light-emitting transistors may have at least two or more source electrode layers formed integrally on the same layer.

In the display, the vertical organic light-emitting transistor may have a source electrode layer made of a conductive material and formed on a main surface of a surface layer as a base.

In the display, a part of the main surface of the surface layer may be formed with a current supply line configured to supply current to the source electrode layer of the vertical organic light-emitting transistor, and the source electrode layer of the vertical organic light-emitting transistor may be formed of the conductive material so as to straddle the surface layer and the current supply line.

The display may further include, on an outer side of the thin-film transistor when viewed from a direction of laminating each layer, a color filter layer that transmits light in a part of a wavelength band of light emitted from the vertical organic light-emitting transistor, in which the gate electrode layer of the vertical organic light-emitting transistor may be formed of a material made of metal oxide that exhibits conductivity and transparency to light.

Here, “the outer side of the thin-film transistor when viewed from the direction of laminating each layer” means an area where the gate electrode layer of the thin-film transistor overlaps with the source electrode layer and the drain electrode layer when viewed from the direction, and further means the outer side of an area in between the source electrode layer and the drain electrode layer, that is, an area in which a channel of the thin-film transistor is formed.

The display may further include a resin layer between the source electrode layer and an organic semiconductor layer of the vertical organic light-emitting transistor, in which the resin layer may be formed with, in an active area of the display, an opening in an area where the source electrode layer and the gate electrode layer of the vertical organic light-emitting transistor overlap with each other when viewed from the direction of laminating each layer.

The “active area” here means a light-emitting area when viewed from the direction of laminating each layer. Specifically, the terms are described with reference to FIG. 1 in the section of “Detailed description of the preferred embodiments”.

The display may further include an auxiliary line that is directly or indirectly connected with one or more current supply lines to help supply and distribute current.

In the display, the auxiliary line may be formed on a same layer in the same process with one of the current-carrying electrode layer of the thin-film transistor.

In the display, the auxiliary line may be formed on a same layer in the same process with the gate electrode layer of the thin-film transistor.

According to the present invention, a manufacturing method of a display including a vertical organic light-emitting transistor in which a wider light-emitting area is secured while suppressing manufacturing time and manufacturing cost is realized.

### BRIEF DESCRIPTION OF DRAWINGS

FIG. 1 is a schematic configuration diagram of a part of a display of an embodiment;

FIG. 2 is a circuit diagram of a light-emitting unit in a display area A1 of FIG. 1;

FIG. 3A is a top view of a schematic element configuration of the light-emitting unit and its periphery of the embodiment;

FIG. 3B is a drawing showing a state where current supply lines 12 are removed from FIG. 3A;

FIG. 4 is a cross-sectional view taken along line A-A′ of FIG. 3A;

FIG. 5A is a schematic view of a periphery of one vertical organic light-emitting transistor of the display in the middle of the manufacturing process when viewed from a +Z side;

FIG. 5B is a schematic view of the periphery of one vertical organic light-emitting transistor of the display in the middle of the manufacturing process when viewed from the +Z side;

FIG. 5C is a schematic view of the periphery of one vertical organic light-emitting transistor of the display in the middle of the manufacturing process when viewed from the +Z side;

FIG. 5D is a schematic view of the periphery of one vertical organic light-emitting transistor of the display in the middle of the manufacturing process when viewed from the +Z side;

FIG. 5E is a schematic view of the periphery of one vertical organic light-emitting transistor of the display in the middle of the manufacturing process when viewed from the +Z side;

FIG. 5F is a schematic view of the periphery of one vertical organic light-emitting transistor of the display in the middle of the manufacturing process when viewed from the +Z side;

FIG. 5G is a schematic view of the periphery of one vertical organic light-emitting transistor of the display in the middle of the manufacturing process when viewed from the +Z side;

FIG. 6 is a cross-sectional view of a schematic element configuration of the light-emitting unit and its periphery of another embodiment when the configuration is cut along an YZ plane;

FIG. 7 is a cross-sectional view of a schematic element configuration of the light-emitting unit and its periphery of another embodiment when the configuration is cut along the YZ plane;

FIG. 8 is a cross-sectional view of a schematic element configuration of the light-emitting unit provided with a color filter layer and its periphery of another embodiment when the configuration is cut along the YZ plane;

FIG. 9A is an enlarged view of a periphery of a thin-film transistor of FIG. 8;

FIG. 9B is a view showing a state before an oxide semiconductor layer of the thin-film transistor of FIG. 9A is formed;

FIG. 10A is a schematic view of a periphery of one vertical organic light-emitting transistor of the display in the middle of the manufacturing process when viewed from the +Z side; and

FIG. 10B is a schematic view of the periphery of one vertical organic light-emitting transistor of the display in the middle of the manufacturing process when viewed from the +Z side.

### DETAILED DESCRIPTION OF THE PREFERRED EMBODIMENTS

Hereinafter, a manufacturing method of a display of the present invention and a configuration of the display manufactured by the method are described with reference to the drawings. In addition, each of the following drawings is schematically shown, and the dimensional ratio and the number of constituents in the drawings do not always match the actual dimensional ratio and the number.

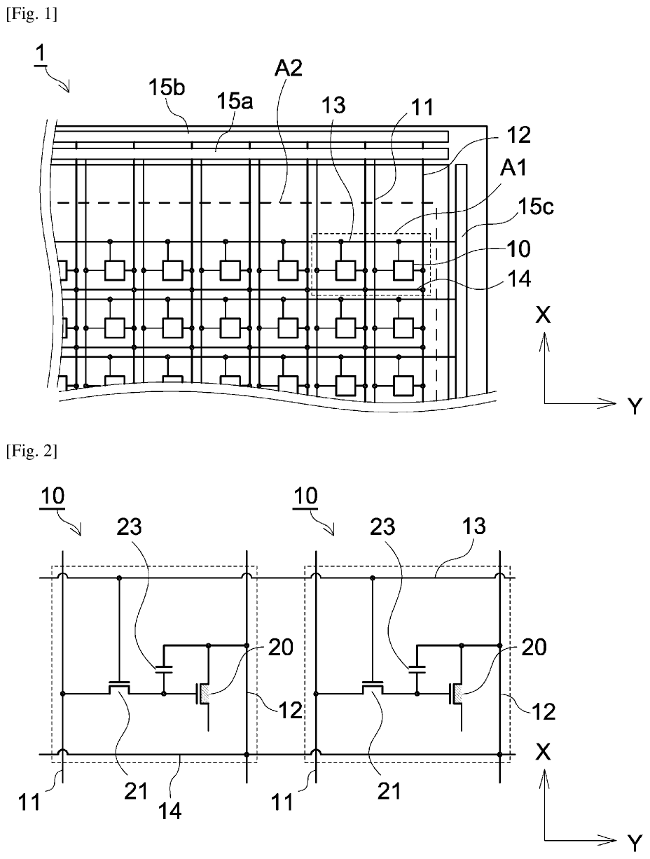

FIG. 1 is a schematic configuration diagram of a part of an embodiment of the display 1. As shown in FIG. 1, the display 1 of the present embodiment includes light-emitting units 10 including later-described vertical organic light-emitting transistors 20, which are aligned in an array, data lines 11, current supply lines 12, and gate lines 13, and auxiliary lines 14.

Further, the display 1 includes, on the outer edge thereof, a source driver 15a that applies to the data line 11 the voltage corresponding to an image data displayed on a gate electrode of the vertical organic light-emitting transistor 20, a current supply unit 15b that supplies the current to the current supply line 12 and supplies the current to a source electrode of the vertical organic light-emitting transistor 20, and a gate driver 15c that outputs a control signal of a thin-film transistor 21 to the gate line 13. Here, as shown in FIG. 1, in the display 1, an area A2 in which the light-emitting units 10 are aligned corresponds to an active area, excluding the area in which the drivers (15a, 15b, 15c) and the like are arranged.

FIG. 2 is a detailed circuit diagram of the light-emitting unit 10 in an area A1 of the display 1 of FIG. 1. As shown in FIG. 2, the light-emitting unit 10 includes the vertical organic light-emitting transistor 20, the thin-film transistor 21 that controls voltage application to the gate electrode of the vertical organic light-emitting transistor 20, and a capacitor 23 formed between the source electrode and the gate electrode of the vertical organic light-emitting transistor 20. In the description of FIGS. 1 and 2, a direction in which the current supply line 12 is wired is described as an X direction, and a direction in which the auxiliary line 14 is wired is described as an Y direction.

The data line 11 is wiring that applies the voltage output from the source driver 15a to the gate electrode of the vertical organic light-emitting transistor 20 through the thin-film transistor 21, in order to adjust the emission brightness of the vertical organic light-emitting transistor 20 according to an image to be displayed. In the present embodiment, the data line 11 is formed in the X direction, but may be formed in the Y direction.

A plurality of the current supply lines 12 are wired in the X direction on the outer side of the vertical organic light-emitting transistors 20 so as to be connected to a group consisting of a plurality of the vertical organic light-emitting transistors 20 aligned in the X direction. Each current supply line 12 supplies the current output from the current supply unit 15b to the source electrode of each vertical organic light-emitting transistor 20 included in the vertical organic light-emitting transistor 20 group.

The gate line 13 is connected to the gate electrode of the thin-film transistor 21, transmits the control signal output from the gate driver 15c toward the gate electrode of the thin-film transistor 21, and switches the thin-film transistor 21 on/off to control the current flowing through the gate electrode of the vertical organic light-emitting transistor 20 and the data line 11. In the present embodiment, the gate line 13 is formed in the Y direction, but may be formed in the X direction.

The auxiliary line 14 is wired in the Y direction between the light-emitting units 10 aligned in the X direction to connect the plurality of current supply lines 12. The auxiliary line 14 may not be formed between all the light-emitting units 10 aligned in the X direction. In the present embodiment, the current supply line 12 is formed in the X direction and the auxiliary line 14 is formed in the Y direction, but the current supply line 12 may be formed in the Y direction and the auxiliary line 14 may be formed in the X direction.

The capacitor 23 is an element for holding the voltage between the gate electrode and the source electrode of the vertical organic light-emitting transistor 20, and is arranged to maintain the displayed image for a predetermined time while the thin-film transistor 21 is in the off state.

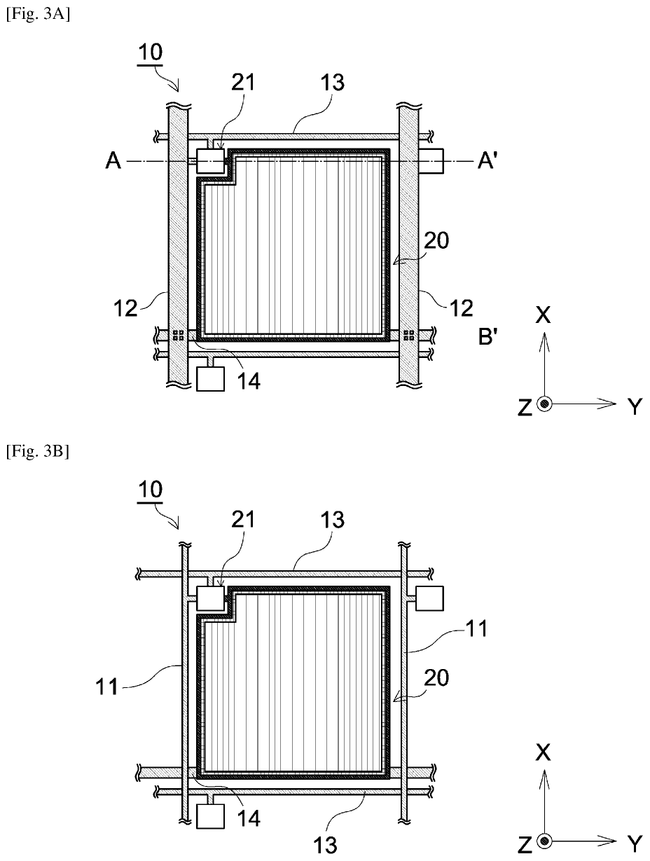

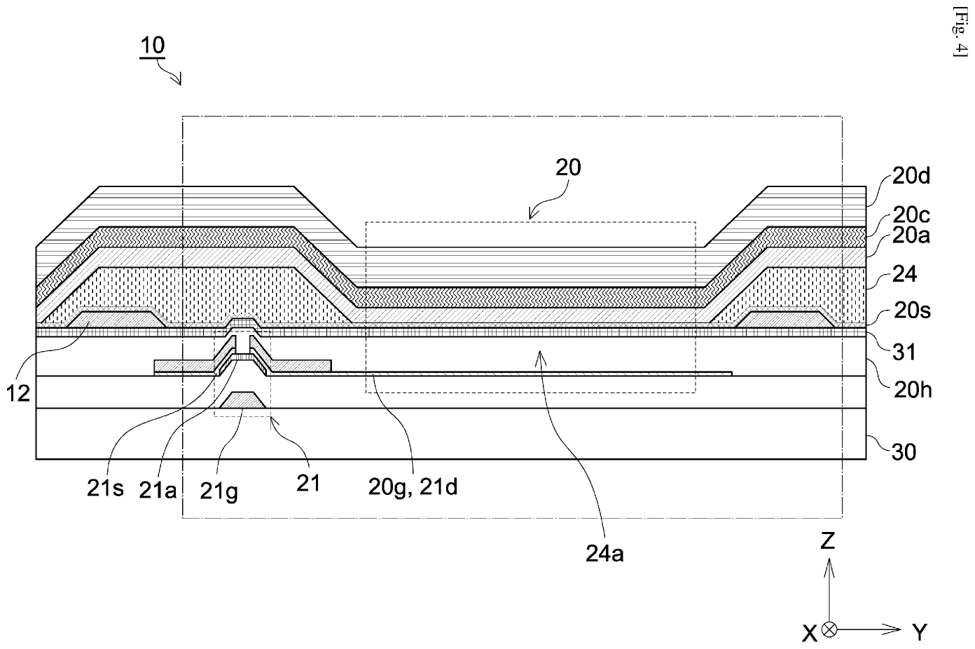

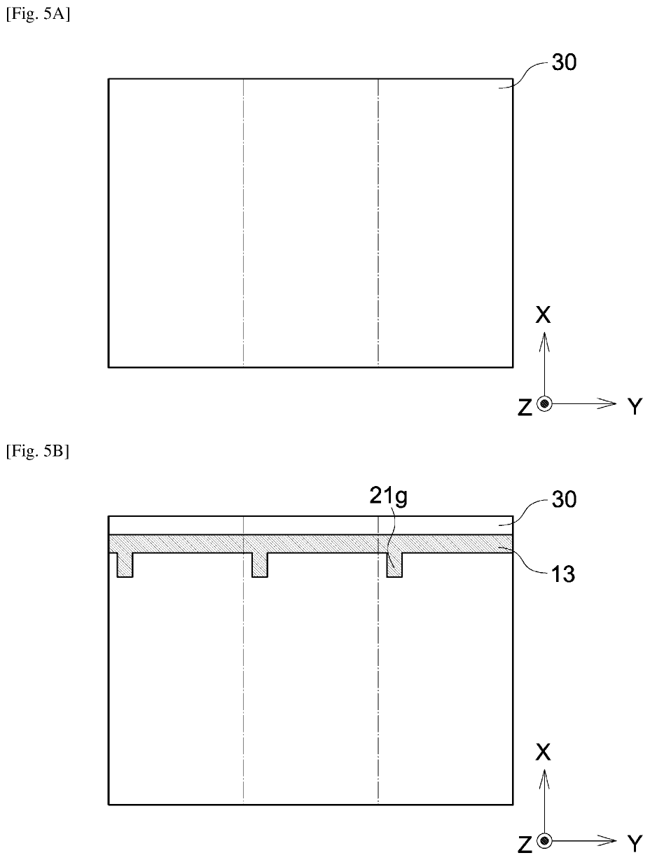

Next, a structure of each element formed on a substrate is described. FIG. 3A is a top view of a schematic element configuration of the light-emitting unit 10 and its periphery according to the embodiment, and FIG. 3B is a view showing a state in which the current supply lines 12 are removed from FIG. 3A. FIG. 4 is a cross-sectional view taken along line A-A′ of FIG. 3A. As shown in FIGS. 3B and 4, the vertical organic light-emitting transistor 20 and the thin-film transistor 21 are formed in a set in an area divided by the data lines 11 and the gate lines 13.

Further, as described above, the vertical organic light-emitting transistor 20 shown in FIGS. 3A and 3B is shown by cutting out a part of the area, but a drain electrode layer 20d, light-emitting layers (an organic semiconductor layer 20a and an organic EL layer 20c), a source electrode layer 20s, and the like of the vertical organic light-emitting transistor 20 of the present embodiment are formed so as to straddle the plurality of vertical organic light-emitting transistors 20 as shown in FIG. 4.

The substrate 30 is transparent to light and emits light radiated from the vertical organic light-emitting transistor 20 to the outside. Specific materials are described later.

In the following description, the direction in which the data line 11 and the current supply line 12 are wired are referred to as the X direction, the direction in which the gate line 13 is wired is referred to as the Y direction, and the direction orthogonal to these is referred to as a Z direction (third direction). In addition, in the case of expressing the direction while distinguishing the positive and negative directions, positive and negative signs are added in the expression such as “+Z direction” and “—Z direction”, and in the case of expressing the direction without distinguishing the positive and negative directions, the expression of “Z direction” is simply used.

The vertical organic light-emitting transistor 20 is constituted of, from the layer on the +Z side, the drain electrode layer 20d corresponding to the cathode electrode, the organic EL layer 20c and the organic semiconductor layer 20a forming the light-emitting layer, the source electrode layer 20s made of conductive material (in the present embodiment, carbon nanotubes) formed on the surface of the surface layer 31, then further on a −Z side, a gate insulating film layer 20h made of dielectric material, and further, a gate electrode layer 20g.

In the vertical organic light-emitting transistor 20 having the above configuration, when the voltage is applied to the gate electrode layer 20g, the Schottky barrier between the organic semiconductor layer 20a and the source electrode layer 20s changes and when a predetermined threshold is exceeded, carriers are injected and the current flows from the source electrode layer 20s to the organic semiconductor layer 20a and the organic EL layer 20c, which causes light to be emitted.

Although the X direction is not shown in FIG. 4, the source electrode layer 20s is also applied to the +Z side of the current supply line 12 formed on the surface layer 31 so as to be in direct contact with the current supply line 12. Then, in order to define the active light emission area in which the carrier injection is controlled by overlapping gate electrode layer 20g by electrically insulating the organic semiconductor layer 20a and the source electrode layer 20s of the vertical organic light-emitting transistor 20 off the active light emission area, a bank layer 24 provided with an opening 24a is formed in an area where the gate electrode layer 20g and the source electrode layer 20s overlap with each other in the Z direction. As shown in FIG. 4, an area in which the opening 24a is formed is preferably formed on the inner side of the area where the gate electrode layer 20g and the source electrode layer 20s overlap with each other, from the viewpoint of ensuring an overlap margin.

The display 1 of the present embodiment is configured such that the substrate 30 is made of material transparent to visible light, and the gate electrode layer 20g and the source electrode layer 20s are configured to have an optical gap and/or morphology through which the visible light can pass. With this configuration, the light emitted from the organic EL layer 20c passes through the substrate 30 and is emitted to the outside to display an image. In addition, the above method of emitting the light is called the “bottom emission method”.

In the thin-film transistor 21, the source electrode layer 21s and the drain electrode layer 21d are connected via the oxide semiconductor layer 21a, and a gate electrode layer 21g is formed below the oxide semiconductor layer 21a with an insulating film layer or a dielectric layer interposed therebetween. When the voltage is applied to the gate electrode layer 21g, a channel is formed in the oxide semiconductor layer 21a, and the current flows through the source electrode layer 21s and the drain electrode layer 21d, which are current-carrying electrode layers.

In the thin-film transistor 21, the source electrode layer 21s is connected to the data line 11. As shown in FIG. 4, some of the conductive layer component of the drain electrode layer 21d of the thin-film transistor 21 is formed integrally with the gate electrode layer 20g of the vertical organic light-emitting transistor 20.

As shown in FIG. 3B, the vertical organic light-emitting transistor 20 is formed so as to fill almost the entire area divided by the data lines 11 and the gate lines 13 in order to maximize the aperture ratio and increase the brightness. The thin-film transistor 21 is formed as small as possible at the corner of the divided area so as to have only a small effect on the light-emitting area of the vertical organic light-emitting transistor 20.

Although the capacitor 23 is not shown in the drawings, in FIGS. 3A to 4, as shown in FIG. 4, in the vertical organic light-emitting transistor 20 of the present embodiment, the source electrode layer 20s and the gate electrode layer 20g are arranged facing each other with the gate insulating film layer 20h interposed therebetween. As a result, the vertical organic light-emitting transistor 20 has the capacitor 23 as a parasitic element, and the capacitor 23 can also exhibit a voltage maintenance function. If the capacitance value of the capacitor 23 of such a parasitic element is insufficient, another capacitor may be additionally formed.

The materials used for each layer are listed below as examples.

The material adopted for the gate line 13 and the auxiliary line 14 may include aluminum (Al), titanium (Ti), molybdenum (Mo), tungsten (W), niobium (Nb), magnesium (Mg), silver (Ag), copper (Cu), and an alloy of combination thereof.

The material adopted for the substrate 30 may include a glass material and a plastic material such as polyethylene terephthalate (PET), polyethylene naphthalate (PEN), and polyimide.

The drain electrode layer 20d of the vertical organic light-emitting transistor 20 may be a single layer or a multilayer, and the material adopted therefor may include carbon nanotube, graphene, Al, lithium fluoride (LiF), molybdenum oxide (MoₓO_{y}), indium tin oxide (ITO), zinc oxide (ZnO), Mg, Ag, gold (Au), and alloys of other combinations.

The material adopted for the gate electrode layer 20g of the vertical organic light-emitting transistor 20 may include ITO and indium gallium zinc oxide (IGZO), which are metal oxide materials exhibiting transparency to light and electrical conductivity. Further, in a configuration in which light is emitted from the side opposite to the gate electrode layer 20g (for example, in a top emission method), a material not having transparency to light may be adopted, and the gate electrode layer 20g may adopt the material such as metal-doped or non-doped transparent conductive oxide including ZnO, indium oxide (In₂O₃), tin dioxide (SnO₂), cadmium oxide (CdO), which are doped with metal such as Al, tin (Sn), yttrium (Y), scandium (Sc), or gallium (Ga), or a material including combination thereof, or Al, Au, Ag, platinum (Pt), cadmium (Cd), nickel (Ni), or tantalum (Ta), or a combination thereof, or further, p or n-doped silicon (Si), or gallium arsenic (GaAs).

The material adopted for the gate insulating film layer 20h between the surface layer 31 and the gate electrode layer 20g of the vertical organic light-emitting transistor 20 may include inorganic and organic compounds such as silicon oxide (SiO), aluminum oxide (Al₂O₃), silicon nitride (Si₃N₄), yttrium oxide (Y₂O₃), lead titanate (PbTiO), aluminum titanate (AlTiO), glass and parylene polymers, polystyrene, polyimide, polyvinylphenol, polymethylmethacrylate, and fluoropolymer.

The material adopted for the organic semiconductor layer 20a of the vertical organic light-emitting transistor 20 may include: linear condensed polycyclic aromatic compounds (or acene compounds) such as naphthalene, anthracene, rubrene, tetracene, pentacene, hexacene, and derivatives thereof; pigments such as copper phthalocyanine (CuPc)-based compounds, azo compounds, perylene-based compounds, and derivatives thereof; low molecular weight compounds such as hydrazone compounds, triphenylmethane-based compounds, diphenylmethane-based compounds, stilbene-based compounds, allylvinyl compounds, pyrazoline-based compounds, triphenylamine derivatives (TPD), allylamine compounds, low molecular weight amine derivatives (a-NPD), 2,2′, 7,7′-tetrakis(diphenylamino)-9,9′-spirobifluorene (spiro-TAD), N,N′-di(1-naphthyl)-N,N′-diphenyl-4,4′-diamonobiphenyl (spiro-NPB), 4,4′, 4″-tris [N-3-methylphenyl-N-phenylamino]triphenylamine (mMTDATA), 2,2′, 7,7′-tetrakis(2,2-diphenylvinyl)-9,9-spirobifluorene (spiro-DPVBi), 4,4′-bis(2,2-diphenylvinyl)biphenyl (DPVBi), (8-quinolinolato)aluminum (Alq), tris(8-quinolinolato)aluminum (Alq3), tris(4-methyl-8 quinolinolato)aluminum (Almq3), and derivatives thereof; polymer compounds such as polythiophene, poly(p-phenylene vinylene) (PPV), biphenyl group-containing polymers, dialkoxy group-containing polymers, alkoxyphenyl PPV, phenyl PPV, phenyl/dialkoxy PPV copolymers, poly(2-methoxy-5-(2′-ethylhexyloxy)-1,4-phenylene vinylene) (MEH-PPV), poly(ethylenedioxythiophene) (PEDOT), poly(styrene sulfonic acid) (PSS), poly(aniline) (PAM), poly(N-vinylcarbazole), poly(vinylpyrene), poly(vinylanthracene), pyreneformaldehyde resins, ethylcarbazoleformaldehyde halide resins, and modifications thereof; n-type transport organic low molecules, oligomers, or polymers such as 5,5-diperfluorohexylcarbonyl-2,2:5,2:5,2-quaterthiophene (DFHCO-4T), DFH-4T, DFCO-4T, P(NDI2OD-T2), PDI8-CN2, PDIF-CN2, F16CuPc, and fullerene, naphthalene, perylene, and oligothiophene derivatives; and further, aromatic compounds having a thiophene ring, such as thieno[3,2-b]thiophene, dinaphthyl[2,3-b: 2′, 3′-f]thieno[3,2-b]thiophene (DNTT), and 2-decyl-7-phenyl[1]benzothioeno[3],2-b][1]benzothiophene (BTBT).

Here, by appropriately selecting organic semiconductors having compatible energy levels, the vertical organic light-emitting transistor 20 can preferably utilize a hole injection layer, a hole transport layer, an organic EL layer, an electron transport layer, an electron injection layer, and the like which are standardly used in a display provided with an organic light-emitting diode. Then, the color of the light emitted to the outside is adjusted so as to emit light of colors such as red, green, and blue by selecting the material constituting the above-described organic EL layer 20c. Further, as described later as another embodiment, the vertical organic light-emitting transistor 20 may be configured to emit white light, and may be configured to select and emit light of a desired color by the color filter layer using the same vertical organic light-emitting transistor 20. Additionally, the vertical organic light-emitting transistor 20 may be configured to emit light of short wavelength such as blue light, and in some pixels may be configured to excite an optical down-conversion layer to emit light of a longer wavelength of desired color such as red and green. The down-conversion layer can include phosphors and semiconductor quantum dots.

The surface layer 31 is a layer formed on the gate insulating film layer 20h for various purposes including fixing the source electrode layer 20s. The material for forming the surface layer 31 can be formed by applying a composition containing a binder resin formed of a silane coupling material, an acrylic resin, or the like.

The material of the bank layer 24 may include inorganic insulating materials such as SiO, Si₃N₄, Al₂O₃, and aluminum nitride (AlN), and organic insulation materials such as polyimide resin, siloxane resin, acrylic resin, and novolac resin.

The material adopted for the oxide semiconductor layer 21a included in the thin-film transistor 21 may include In—Ga—Zn—O-based semiconductors, Zn—O-based semiconductors (ZnO), In—Zn—O-based semiconductors (IZO (registered trademark)), Zn—Ti—O-based semiconductors (ZTO), Cd—Ge—O-based semiconductors, Cd—Pb—O-based semiconductors, CdO (cadmium oxide), Mg—Zn—O-based semiconductors, In—Sn—Zn—O-based semiconductors (for example, In₂O₃—SnO₂—ZnO), and In—Ga—Sn—O-based semiconductors.

In the present embodiment, the thin-film transistor 21 is a thin-film transistor with the semiconducting channel layer made of an oxide semiconductor, but may be a thin-film transistor made of an amorphous silicon, a low temperature polysilicon (LTPS), or a high temperature polysilicon (HTPS). Further, the thin-film transistor may be either p-type or n-type. Further, as a specific configuration, any configuration such as a staggerd type, an inverted staggerd type, a coplanar type, and an inverted coplanar type can be adopted.

As the vertical organic light-emitting transistor 20, the vertical organic light-emitting transistors 20 described in Patent Documents 1 and 2 can also be adopted.

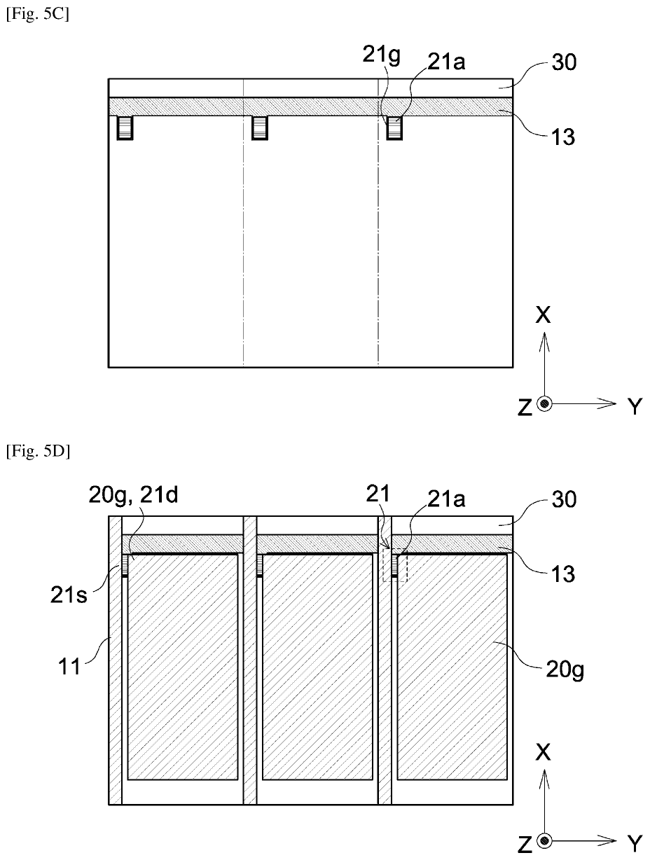

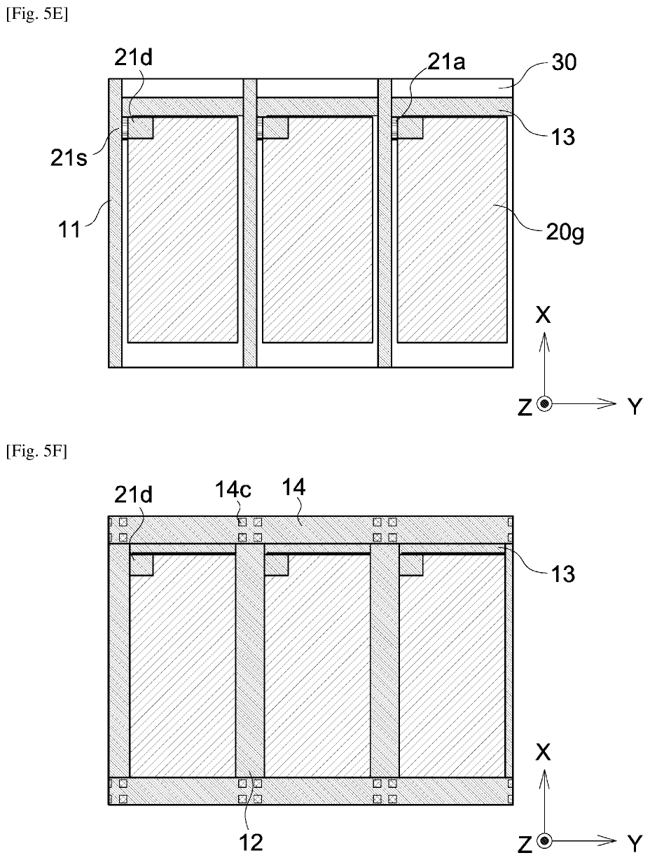

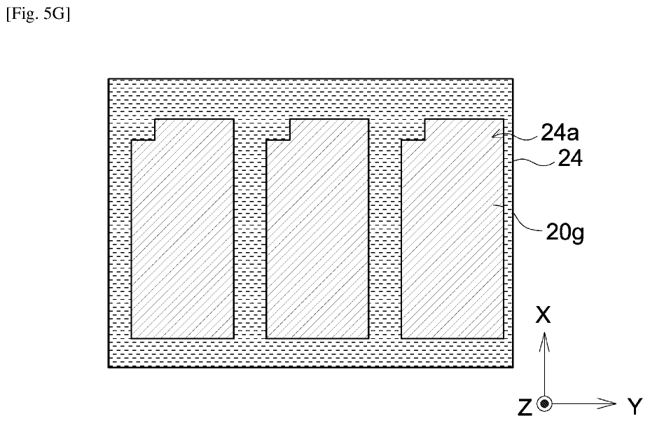

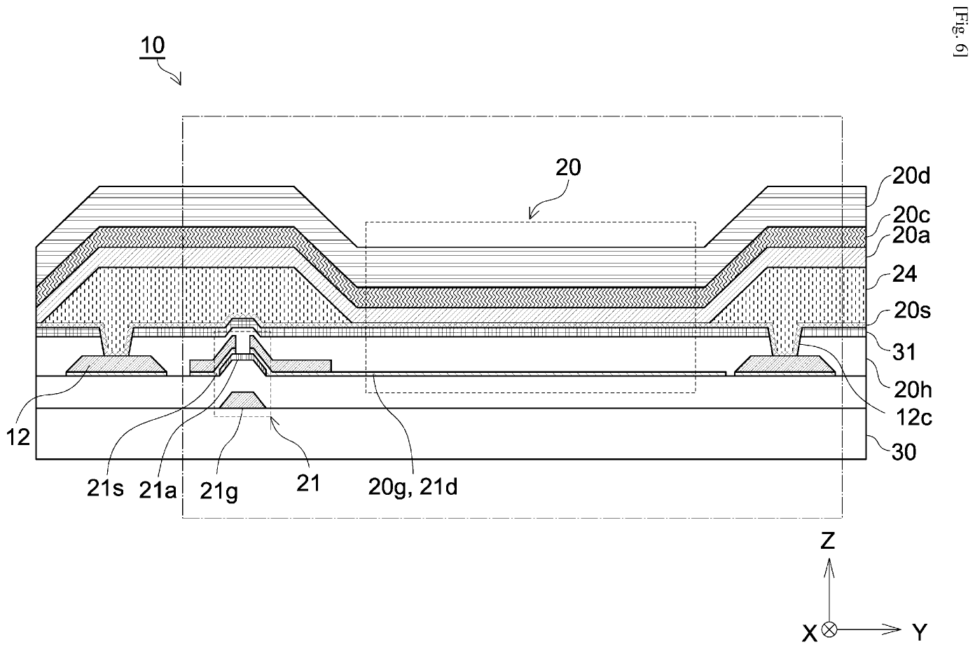

Next, the manufacturing process of each layer is briefly described. FIGS. 5A to 5G are schematic views of the periphery of the vertical organic light-emitting transistor 20 of the display 1 in the middle of the manufacturing process when viewed from the +Z side. Hereinafter, each process is described with reference to the drawings.

In addition, the description is made referring to the drawing in which three vertical organic light-emitting transistors 20 are aligned in the Y direction so that the positional relationship with the adjacent vertical organic light-emitting transistors 20 and the structure between the vertical organic light-emitting transistors 20, that is, the structure on the outer side of the vertical organic light-emitting transistors 20 can be understood.

The outside of the illustrated area does not have to be repeated in the same pattern. For example, as shown in FIG. 5D and the like, the thin-film transistors 21 are formed on the (+X, −Y) side, but in the entire display 1, on the −X side of the central portion in the X direction, the thin-film transistor may be formed in any pattern such as on the (−X, +Y) side. Further, in the display 1, the size of the pixels may be optionally changed for each pixel displaying a different color.

As shown in FIG. 5A, first, the substrate 30 is prepared (step S1).

After step S1, as shown in FIG. 5B, the gate electrode layer 21g of the thin-film transistor 21 and the gate line 13 connected to the gate electrode layer 21g are formed on the substrate 30 (step S2).

After step S2, an insulating film (not shown) is formed over the entire surface, and as shown in FIG. 5C, the oxide semiconductor layer 21a is formed on the +Z side of the gate electrode layer 21g of the thin-film transistor 21 (step S3).

The term “formed over the entire surface” here means that the layer is formed over the entire image forming area in which the vertical organic light-emitting transistor 20 is formed, and does not mean that the layer is formed over the entire outer edge portion where the driver is arranged. This also applies to the following description.

After step S3, as shown in FIG. 5D, the drain electrode layer 21d and the data line 11 are formed on the oxide semiconductor layer 21a of the thin-film transistor 21 to be separated in the Y direction (step S4). The data line 11 constitutes the source electrode layer 21s of the thin-film transistor 21 at a portion overlapping with the oxide semiconductor layer 21a in the Z direction. In the present embodiment, in step S4, the configuration has a shape as shown in FIG. 5E because a two-step forming process by halftone exposure is performed, but step S4 may not be the forming process by halftone exposure.

After step S4, a passivation film is formed over the entire surface, and then the surface layer 31 is formed over the entire surface (step S5). The passivation film can serve as the gate insulating film layer 20h, or a separate gate insulating film layer 20h can be formed. The passivation film and the surface layer 31 are not shown for convenience of explanation.

After step S5, as shown in FIG. 5F, the current supply line 12 is formed in the X direction, and the auxiliary line 14 is formed so as to connect the current supply line 12 to other current supply lines in the Y direction (step S6). In the present embodiment, because the current supply line 12 and the auxiliary line 14 are formed in different layers, contact holes 14c connecting the layers are also formed. The contact holes 14c may be formed at any location and in an appropriate shape and number.

After step S6, on the main surface of the surface layer 31 formed in step S4 and the current supply line 12 formed in step S5, the source electrode layer 20s is integrally formed over the entire surface layer 31 across the plurality of vertical organic light-emitting transistors aligned in the X direction (step S7). Similarly to the surface layer 31, the source electrode layer 20s is not shown for convenience of explanation.

After step S7, as shown in FIG. 5G, the bank layer 24, which is a resin layer, is formed (step S8). When viewed from the Z direction, the bank layer 24 is formed with the opening 24a formed in the area where the gate electrode layer 20g and the source electrode layer 20s overlap with each other. The bank layer 24 may be formed of the inorganic insulating material as described above.

After step S8, the organic semiconductor layer 20a and the organic EL layer 20c, which are to be the light-emitting layers, and the drain electrode layer 20d are formed over the entire surface to form the configurations shown in FIGS. 3A to 4.

In the manufacturing process as described above, the gate electrode layer 20g of the vertical organic light-emitting transistor 20 and the drain electrode layer 21d of the thin-film transistor 21 are formed at the same time. Therefore, the display can be manufactured with fewer processes than in the conventional manufacturing process.

In the present embodiment, all of the drain electrode layer 20d, the organic semiconductor layer 20a, the organic EL layer 20c, and the source electrode layer 20s of the vertical organic light-emitting transistor 20 straddle the plurality of vertical organic light-emitting transistors 20. However, any of the above may be formed for each vertical organic light-emitting transistor 20.

### Other Embodiments

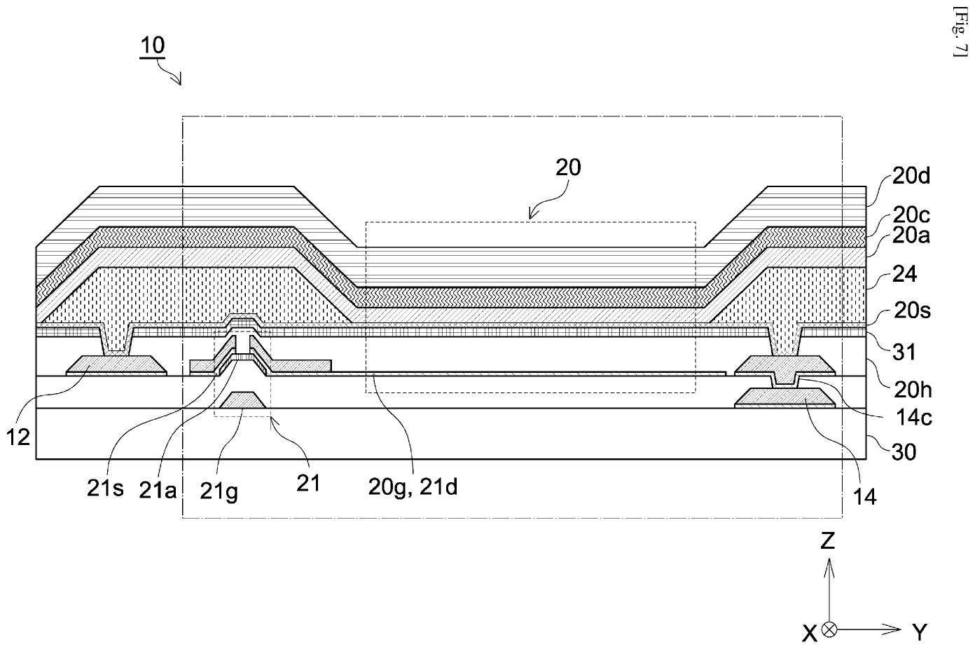

Hereinafter, other embodiments are described.

<1> FIGS. 6 and 7 are cross-sectional views of schematic element configurations of the light-emitting units 10 and their peripheries of another embodiment when the configurations are cut in the YZ plane. As shown in FIG. 6, the current supply line 12 may be formed in a layer on the −Z side of the surface layer 31. Further, as shown in FIG. 7, the auxiliary line 14 may be formed in a layer on the −Z side of the current supply line 12.

In the case of configuring the light-emitting unit 10 of FIG. 6, for example, the current supply line 12 is formed by halftone exposure in step S4. Further, in the case of configuring the light-emitting unit 10 of FIG. 7, for example, the auxiliary line 14 is formed at the same time as the gate electrode layer 21g of the thin-film transistor 21 is formed in step S2.

The light-emitting unit 10 having the configuration as shown in FIG. 6 can have the current supply line 12 formed at the same time when each electrode layer of the thin-film transistor 21 is formed, and in that case, the process of forming contact holes 12c is required. However, the process of forming these contact holes 12c is a process that is originally performed for the connection between the electrode layers in the peripheral portion of the display even in the conventional manufacturing process of the light-emitting diode display, and does not become a factor that increases the number of processes. Therefore, the number of processes is reduced as compared with the conventional manufacturing method.

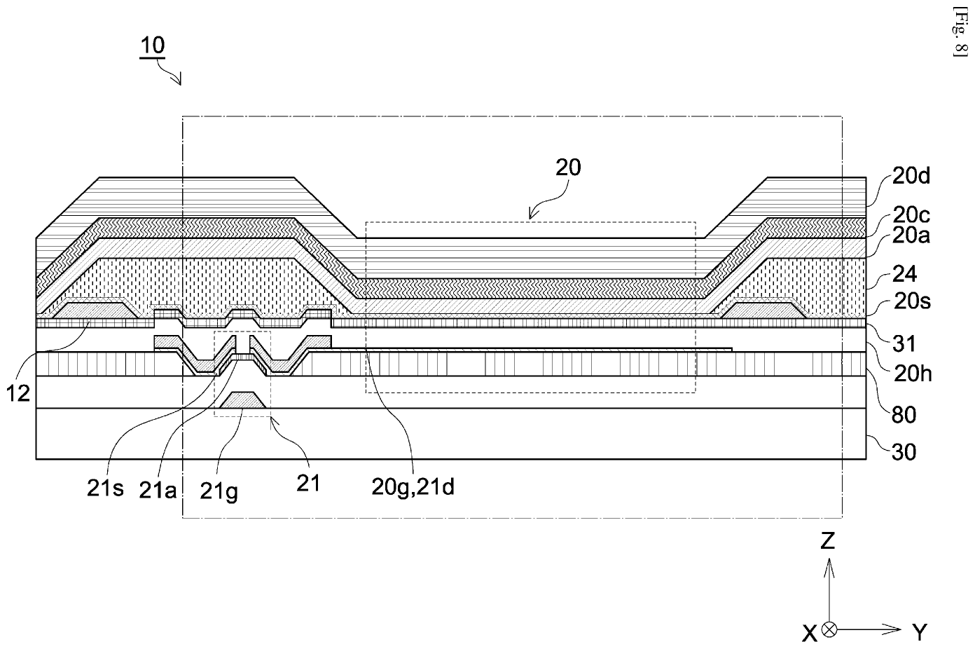

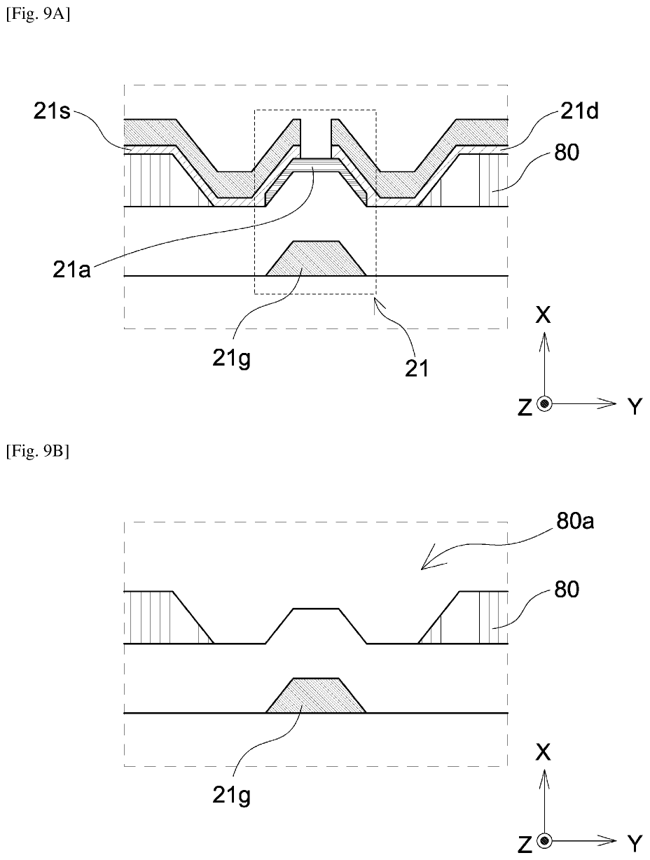

The light-emitting unit 10 having the configuration as shown in FIG. 7 can have the auxiliary line 14 formed at the same time when each electrode layer of the thin-film transistor 21 is formed, and in that case, the process of forming the contact holes 14c are required in addition to the configuration shown in FIG. 6. However, the number of processes of forming the contact holes 14c is less than the number of processes of newly creating the current supply line 12 in the upper layer, and the auxiliary line 14 can be formed while the number of processes is suppressed, and further, the process of forming the contact holes 14c can be alternatively utilized as the process of connecting between the wirings. Therefore, the number of processes is reduced as compared with the conventional manufacturing method. Therefore, both of the configurations shown in FIGS. 6 and 7 can be manufactured at a lower cost as compared with the manufacturing processes described with reference to FIGS. 5A to 5G.

<2> FIG. 8 is a cross-sectional view a schematic element configuration of the light-emitting unit 10 provided with a color filter layer 80 and its periphery of another embodiment when the configuration is cut along the YZ plane. FIG. 9A is an enlarged view of the periphery of the thin-film transistor 21 of FIG. 8, and FIG. 9B is a view showing a state before the oxide semiconductor layer 21a of the thin-film transistor 21 of FIG. 9A is formed. As shown in FIGS. 8 and 9A, the color filter layer 80 may be formed on the −Z side of the gate electrode layer 20g of the vertical organic light-emitting transistor 20. The process of forming the color filter layer 80 is performed before the oxide semiconductor layer 21a of the thin-film transistor 21 is formed in step S3.

At this time, an opening 80a is created in the color filter layer 80 around the position where the thin-film transistor 21 is formed and the color filter layer 80 is not formed in the opening, and as shown in FIG. 9B, the opening 80a of the color filter layer 80 is formed in a forward tapered shape that gradually narrows toward the substrate 30, and as a result, the thin-film transistor 21 can be formed and operated. The color filter layer 80 may be formed by such as a method of exposing a photosensitive color filter material through a photomask and developing the same to form a color filter with a predetermined pattern, a method of forming the color filter layer 80 once on the entire surface and thereafter, performing an etching process, or a method of forming the color filter while the area in which the thin-film transistor 21 is formed is treated with masking processing.

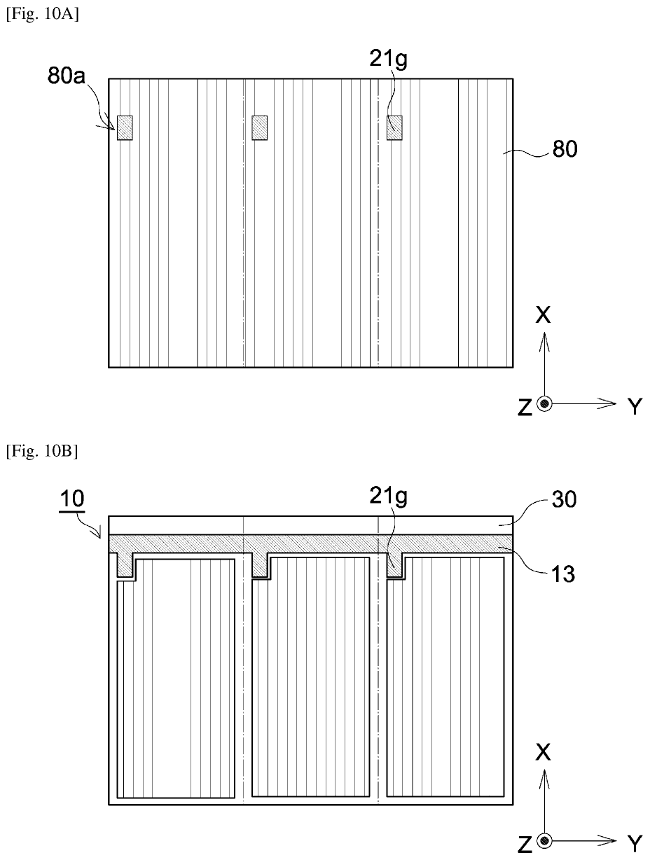

FIGS. 10A and 10B are schematic views of a periphery of one vertical organic light-emitting transistor of the display in the middle of the manufacturing process when viewed from the +Z side, in the case of forming the color filter layer 80. FIG. 10A shows an example in the case where the color filter layer 80 is formed over the entire surface after step S2 and then the opening 80a is formed, and FIG. 10B shows an example in the case where the color filter layer 80 is individually formed for each light-emitting unit 10.

The configuration shown in FIG. 8 is an example of the case where the bottom emission method is adopted in which the light is emitted from the substrate 30 side through the color filter layer 80. Among the light emitted from the vertical organic light-emitting transistor 20, the light in a part of the wavelength band is filtered by the color filter layer 80, and the light in the remaining wavelength band is emitted from the substrate 30.

In the case of this configuration, the gate electrode layer 20g is preferably formed of a material exhibiting transparency to light so that the light emitted from the organic EL layer 20c of the vertical organic light-emitting transistor 20 reaches the substrate 30, and for example, the metal oxide materials such as ITO and IGZO as described above may be adopted.

<3> Although each of the above-described embodiments has been described on the premise of the bottom emission method, the “top emission method” that emits light from the side opposite to the substrate 30 may be adopted. In this case, in the vertical organic light-emitting transistor 20, the drain electrode layer 20d is formed of a material exhibiting transparency to light so that the light emitted from the organic EL layer 20c is taken out.

<4> The configurations, materials, and manufacturing processes included in the display 1 described above in each embodiment are merely examples, and the present invention is not limited to the configurations described above and the processes shown.

### REFERENCE SIGNS LIST

1 Display
10 Light-emitting unit
11 Data line
12 Current supply line
12c Contact hole
13 Gate line
14 Auxiliary line
14c Contact hole
15a Source driver
15b Current supply unit
15c Gate driver
20 Vertical organic light-emitting transistor
20a Organic semiconductor layer
20c Organic EL layer
20d Drain electrode layer
20g Gate electrode layer
20h Gate insulating film layer
20s Source electrode layer
21 Thin-film transistor
21a Oxide semiconductor layer
21c Contact hole
21d Drain electrode layer
21g Gate electrode layer
21s Source electrode layer
23 Capacitor
24 Bank layer
24a Opening
30 Substrate
31 Surface layer
80 Color filter layer
80a Opening

1. A manufacturing method of a display comprising a vertical organic light-emitting transistor, the method comprising:
forming integrally on a same layer, a gate electrode layer of the vertical organic light-emitting transistor and one of current-carrying electrode layers of a thin-film transistor connected to the gate electrode layer of the vertical organic light-emitting transistor.

2. The manufacturing method of the display according to claim 1, wherein the vertical organic light-emitting transistors have at least two or more source electrode layers formed integrally on the same layer.

3. The manufacturing method of the display according to claim 1, wherein the source electrode layer of the vertical organic light-emitting transistor is formed after a surface layer serving as a base is formed, by forming a thin film or a percolating network of a conductive material on a main surface of the surface layer.

4. The manufacturing method of the display according to claim 3, wherein
after the surface layer is formed, a part of the main surface of the surface layer is formed with a current supply line configured to supply current to the source electrode layer of the vertical organic light-emitting transistor, and
after the current supply line is formed, the source electrode layer of the vertical organic light-emitting transistor is formed of the conductive material so as to straddle the surface layer and the current supply line.

5. The manufacturing method of the display according to claim 1, wherein the gate electrode layer of the vertical organic light-emitting transistor is formed of a material made of metal oxide that exhibits conductivity and transparency to light.

6. The manufacturing method of the display according to claim 5, further comprising forming, on an outer side of the thin-film transistor when viewed from a direction of laminating each layer, a color filter layer that transmits light in a part of a wavelength band of light emitted from the vertical organic light-emitting transistor.

7. A display comprising:
a vertical organic light-emitting transistor; and
a thin-film transistor in which one of current-carrying electrode layers is connected to a gate electrode layer of the vertical organic light-emitting transistor, wherein the gate electrode layer of the vertical organic light-emitting transistor and the one of the current-carrying electrode layer of the thin-film transistor connected to the gate electrode layer of the vertical organic light-emitting transistor are formed integrally on a same layer.

8. The display according to claim 7, wherein the vertical organic light-emitting transistors have at least two or more source electrode layers formed integrally on the same layer.

9. The display according to claim 7, wherein the source electrode layer of the vertical organic light-emitting transistor is made of a conductive material and formed on a main surface of a surface layer serving as a base.

10. The display according to claim 9, wherein
a part of the main surface of the surface layer is formed with a current supply line configured to supply current to the source electrode layer of the vertical organic light-emitting transistor, and
the source electrode layer of the vertical organic light-emitting transistor is formed of the conductive material so as to straddle the surface layer and the current supply line.

11. The display according to claim 7, wherein the gate electrode layer of the vertical organic light-emitting transistor is formed of a material made of metal oxide that exhibits conductivity and transparency to light.

12. The display according to claim 11, further comprising, on an outer side of the thin-film transistor when viewed from a direction of laminating each layer, a color filter layer that transmits light in a part of a wavelength band of light emitted from the vertical organic light-emitting transistor.

13. The display according to claim 7, further comprising a resin layer between the source electrode layer and an organic semiconductor layer of the vertical organic light-emitting transistor, wherein
the resin layer is formed with, in an active area of the display, an opening in an area where the source electrode layer and the gate electrode layer of the vertical organic light-emitting transistor overlap with each other when viewed from the direction of laminating each layer.

14. The display according to claim 7, further comprising an auxiliary line that is directly or indirectly connected with one or more current supply lines to help supply and distribute current.

15. The display according to claim 14, wherein the auxiliary line is formed on a same layer in the same process with one of the current-carrying electrode layer of the thin-film transistor.

16. The display according to claim 14, wherein the auxiliary line is formed on a same layer in the same process with the gate electrode layer of the thin-film transistor.
